(19) United States
(12) Patent Application Publication
(10) Pub. No.: US 2019/0067338 A1
(43) Pub. Date: Feb. 28, 2019

(54) Amoled Substrate and Method for Manufacturing Same

(71) Applicant: Wuhan China Star Optoelectronics Semiconductor DisplayTechnology Co., Ltd., Wuhan, Hubei (CN)

(72) Inventor: Tiyao Ma, Wuhan (CN)

(73) Assignee: Wuhan China Star Optoelectronics Semiconductor Display Technology Co., Ltd., Wuhan, Hubei (CN)

(21) Appl. No.: 15/574,080

(22) PCT Filed: Nov. 8, 2017
(86) PCT No.: PCT/CN2017/109832

§ 371 Date: Nov. 14, 2017

(30) Foreign Application Priority Data
Aug. 28, 2017 (CN) 201710747902.5

(51) Int. Cl. H01L 27/12

(52) U.S. Cl. CPC H01L 27/1262; H01L 27/3244; H01L 27/1274; H01L 27/1218

(57) ABSTRACT

The present disclosure provides a method for manufacturing an AMOLED substrate and an AMOLED substrate. The method includes the steps of: providing a base substrate; forming a PI film on the base substrate; and sequentially forming a separation layer, a non-metallic layer, a buffer layer, and a TFT array on the PI film; wherein the non-metallic layer formed above the PI film is configured for absorbing a laser passing through the buffer layer during formation of the TFT array.

### FIELD OF THE DISCLOSURE

The present disclosure relates to the field of display techniques, and more particularly to an active matrix organic light-emitting diode (AMOLED) substrate and a method for manufacturing the same.

### BACKGROUND

With development of display techniques, manufacturing process of AMOLED display is much more mature than before and AMOLED display apparatus has been utilized in a variety of display applications.

In a manufacturing process of an AMOLED display, a polyimide (PI) base plate is provided first, and a thin film transistor (TFT) array is formed on the PI base plate. The PI base plate is used because of its good high-temperature resistant ability, chemical resistant ability, and water/oxygen-blocking property. In addition, an excimer laser annealing process is carried out during formation of the TFT array. However, during formation of the TFT array, the laser used in the excimer laser annealing process would pass through the buffer layer and the separation layer and damage the PI base plate. In particular, the laser scorches the PI base plate where such defect cannot be repaired.

According to the prior art, a method for manufacturing an AMOLED substrate includes:

a step 1 of cleansing a glass substrate;

a step 2 of forming a PI film on the glass substrate;

a step 3 of drying and curing the PI film;

a step 4 of forming a separation layer on the PI film; and

a step 5 of forming a buffer layer on the separation layer.

### SUMMARY OF THE DISCLOSURE

The present disclosure provides an AMOLED substrate and a method for manufacturing the same. The present disclosure solves the problems encountered by the prior art, where laser passes through the buffer layer and the separation layer, and damages or even scorches the PI film in the excimer laser annealing process during formation of TFT array.

To achieve the above mentioned objective, the present disclosure provides the following technical schemes.

In one aspect, the present disclosure provides a method for manufacturing an active matrix organic light-emitting diode (AMOLED) substrate, comprising:

a step S10 of providing a base substrate;

a step S20 of forming a polyimide (PI) film on the base substrate;

a step S30 of forming a separation layer on the PI film;

a step S40 of forming a non-metallic layer on the separation layer;

a step S50 of forming a buffer layer on the non-metallic layer; and

a step S60 of forming a thin film transistor (TFT) array on the buffer layer using an excimer laser annealing process, wherein a wavelength of an excimer laser used in the excimer laser annealing process is 308 nm;

wherein the non-metallic layer formed above the PI film is configured for absorbing a laser passing through the buffer layer during formation of the TFT array.

In accordance with one preferred embodiment of the present disclosure, the non-metallic layer includes an amorphous silicon layer and a silicon oxide layer with one stacked on the other.

In accordance with one preferred embodiment of the present disclosure, the buffer layer is a silicon nitride layer.

In accordance with one preferred embodiment of the present disclosure, the silicon oxide layer is disposed on one surface of the amorphous silicon layer adjoining to the silicon nitride layer.

In accordance with one preferred embodiment of the present disclosure, the step S40 includes:

using a plasma enhanced chemical vapor deposition (PECVD) process to form the non-metallic layer on the separation layer.

In another aspect, the present disclosure provides an active matrix organic light-emitting diode (AMOLED) substrate comprising: a base substrate, a polyimide (PI) film, a separation layer, a non-metallic layer, a buffer layer, and a thin film transistor (TFT) array sequentially stacked from bottom to top,

wherein the non-metallic layer disposed above the PI film is configured for absorbing a laser passing through the buffer layer during formation of the TFT array.

In accordance with one preferred embodiment of the present disclosure, the non-metallic layer includes an amorphous silicon layer and a silicon oxide layer with one stacked on the other.

In accordance with one preferred embodiment of the present disclosure, the buffer layer is a silicon nitride layer.

In accordance with one preferred embodiment of the present disclosure, the silicon oxide layer is disposed on one surface of the amorphous silicon layer adjoining to the silicon nitride layer.

Additionally, the present disclosure provides a method for manufacturing an active matrix organic light-emitting diode (AMOLED) substrate, comprising:

a step S10 of providing a base substrate;

a step S20 of forming a polyimide (PI) film on the base substrate;

a step S30 of forming a separation layer on the PI film;

a step S40 of forming a non-metallic layer on the separation layer;

a step S50 of forming a buffer layer on the non-metallic layer; and

a step S60 of forming a thin film transistor (TFT) array on the buffer layer using an excimer laser annealing process;

wherein the non-metallic layer formed above the PI film is configured for absorbing a laser passing through the buffer layer during formation of the TFT array.

In accordance with one preferred embodiment of the present disclosure, the non-metallic layer includes an amorphous silicon layer and a silicon oxide layer with one stacked on the other.

In accordance with one preferred embodiment of the present disclosure, the buffer layer is a silicon nitride layer.

In accordance with one preferred embodiment of the present disclosure, the silicon oxide layer is disposed on one surface of the amorphous silicon layer adjoining to the silicon nitride layer.

In accordance with one preferred embodiment of the present disclosure, the step S40 includes:

using a plasma enhanced chemical vapor deposition (PECVD) process to form the non-metallic layer on the separation layer.

The present disclosure provides an AMOLED substrate and a method for manufacturing the same. According to the present disclosure, a non-metallic layer is formed on the separation layer in order to absorb a laser passing through the buffer layer during formation of the TFT array, thus preventing any adverse effect caused by the laser on the PI film and increasing manufacturing efficiency of AMOLED substrate.

### BRIEF DESCRIPTION OF THE DRAWINGS

To detailedly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 shows a flowchart of a method for manufacturing an AMOLED substrate according to one embodiment of the present disclosure.

FIG. 2 is a cross-sectional view of an AMOLED substrate according to one embodiment of the present disclosure.

FIGS. 3A-3F are flow diagrams showing cross-sectional views of an AMOLED substrate during a manufacturing process thereof according to one embodiment of the present disclosure.

FIG. 4 is a cross-sectional view of an AMOLED substrate according to another embodiment of the present disclosure.

FIG. 5 is a cross-sectional view of an AMOLED substrate according to a further embodiment of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

The present disclosure provides a method for manufacturing an AMOLED substrate and a method for manufacturing an AMOLED display apparatus. The present disclosure solves the problems encountered by the prior art, where laser passes through the buffer layer and the separation layer, and damages or even scorches the PI film in the excimer laser annealing process during formation of TFT array.

Detailed explanation will be provided for preferred embodiments of the present disclosure in the following description with reference to the accompanying drawings.

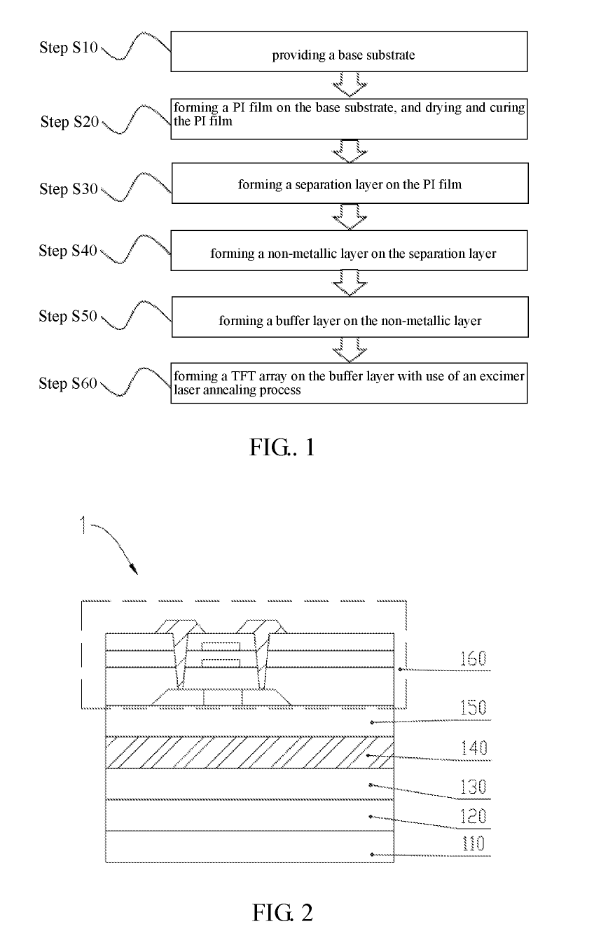

FIG. 1 shows a flowchart of a method for manufacturing an AMOLED substrate according to one embodiment of the present disclosure. FIG. 2 is a cross-sectional view of an AMOLED substrate 1 according to one embodiment of the present disclosure. The present disclosure provides a method for manufacturing an AMOLED substrate including the following steps.

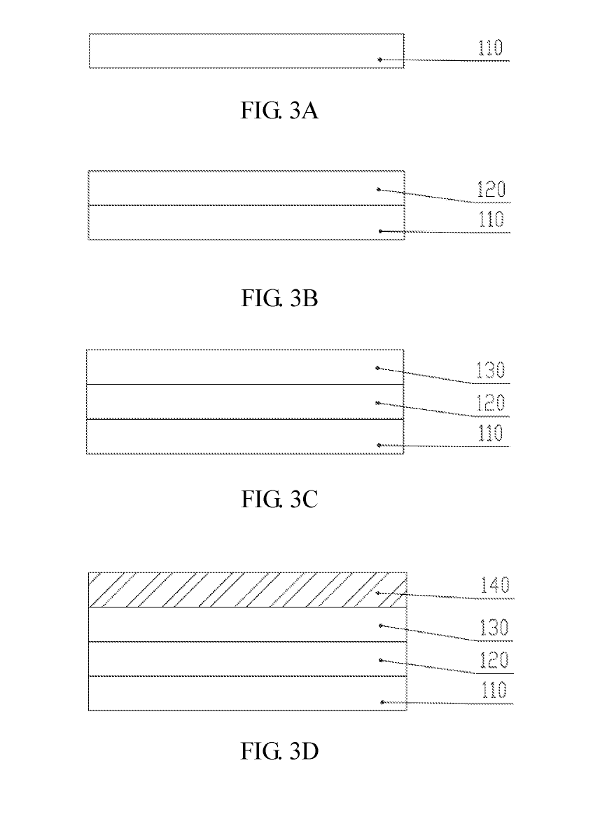

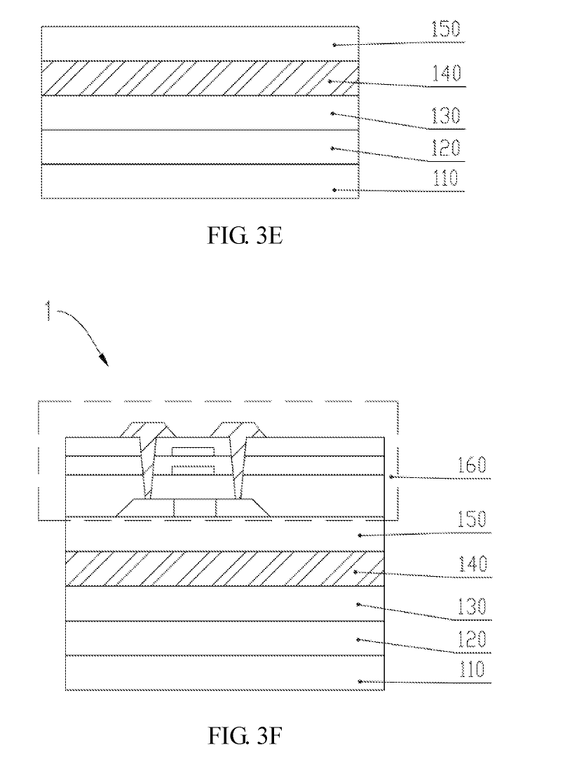

As shown in FIG. 3A, in step S10, a base substrate 110 is provided.

The base substrate 110 provided in the step S10 is a rigid base substrate, which is generally made of glass. The base substrate 110 would be normally separated from a flexible substrate once formation of AMOLED is completed.

As shown in FIG. 3B, in a step S20, a PI film 120 is formed on the base substrate 110, and the PI film 120 is dried and cured.

Specifically, in the step S20, after the base substrate 110 is cleansed, a layer of PI solution is coated on surface of the base substrate 110 by use of a needle spray coating method. Thereafter, the PI solution is dried and cured, such that a dried and cured PI film 120 is formed.

The PI film 120 serves as a flexible substrate on which AMOLED will be formed, and the PI film 120 is a transparent plastic film having good electrical insulation property, abrasion resistant property, high-temperature resistant ability, chemical resistant ability, and water/oxygen-blocking property.

The PI film 120 would be damaged if the PI film 120 is irradiated by a laser having a wavelength within a certain range. Therefore, during manufacturing process of AMOLED substrate 1, it is preferable to avoid the laser from directly irradiating the PI film 120.

As shown in FIG. 3C, in a step S30, a separation layer 130 is formed on the PI film 120.

The separation layer 130 formed in the step S30 is used for preventing the PI film 120 from contacting other layers of the AMOLED substrate 1, where such contact would cause damage or corrosion of the PI film 120.

As shown in FIG. 3D, in a step S40, a non-metallic layer 140 is formed on the separation layer 130.

The step S40 is an essential step in the present disclosure. The non-metallic layer 140 is formed on surface of the separation layer 130. The non-metallic layer 140 does not directly contact the PI film 120, therefore the non-metallic layer 140 would not cause any adverse effect on property of the PI film 120.

The non-metallic layer 140 is composed of amorphous silicon and silicon oxide. Amorphous silicon has good absorption ability for laser having wavelength of 308 nm, and silicon oxide helps to adhere amorphous silicon to the buffer layer 150 made of silicon nitride.

The non-metallic layer 140 can have a structure including either two layers or single one layer.

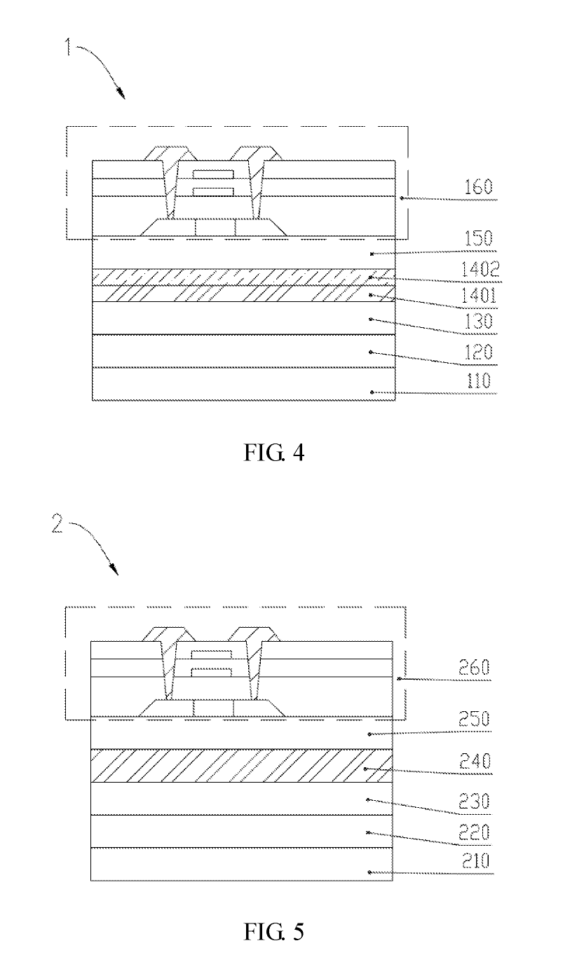

As shown in FIG. 4, in case that the non-metallic layer 140 is composed of two layers, the non-metallic layer 140 includes an amorphous silicon layer 1401 and a silicon oxide layer 1402. The amorphous silicon layer 1401 is disposed on surface of the separation layer 130. The silicon oxide layer 1402 is disposed on surface of the amorphous silicon layer 1401, and directly contacts the buffer layer 150 which is made of silicon nitride and will be formed in the next step.

As shown in FIG. 2, in case that the non-metallic layer 140 is composed of single one layer, the non-metallic layer 140 includes amorphous silicon and silicon oxide, where amorphous silicon and silicon oxide are mixed together.

In the step S40, a plasma enhanced chemical vapor deposition (PECVD) process is generally used to form the non-metallic layer 140 on the separation layer 130.

During the PECVD process, chemical vapor deposition is carried out to form the non-metallic layer 140 in an environment filled with plasma.

Presence of plasma facilitates decomposition and combination of gas molecules, and facilitates generation of active radicals. Moreover, plasma provides energy required for second-generation molecules to diffuse to surface of the substrate, and thus some reactions expected to occur under high temperature can be realized under low temperature.

Use of PECVD process to form the non-metallic layer 140 achieves adjustment of the stress of the formed non-metallic layer 140 by modulation of high/low frequency. In addition, bombardment by plasma can remove impurities on surface of the non-metallic layer 140, therefore adhesive ability of the non-metallic layer 140 is increased.

As shown in FIG. 3E, in a step S50, a buffer layer 150 is formed on the non-metallic layer 140.

The buffer layer 150 is formed from silicon nitride. And, the buffer layer 150 is configured for resulting in a uniform planar surface of the substrate which will be used as a base for the next step of formation of TFT array 160.

As shown in FIG. 3F, in a step S60, a TFT array 160 is formed on the buffer layer 150 using an excimer laser annealing process.

In the step S60, wavelength of an excimer laser used in the excimer laser annealing process is 308 nm.

Please refer to FIG. 5. In accordance with the above mentioned objective of the present disclosure, the present disclosure further provides an AMOLED substrate 2, comprising: a base substrate 210, a PI film 220, a separation layer 230, a non-metallic layer 240, a buffer layer 250, and a TFT array 260 sequentially stacked from bottom to top.

The non-metallic layer 240 disposed above the PI film 220 is configured for absorbing a laser passing through the buffer layer 250 during formation of the TFT array 260.

The base substrate 210 is a rigid base substrate, which is generally made of glass. The base substrate 210 would be normally separated from a flexible substrate once formation of AMOLED is completed.

The PI film 220 serves as a flexible substrate on which AMOLED will be formed, and the PI film 220 is a transparent plastic film having good electrical insulation property, abrasion resistant property, high-temperature resistant ability, chemical resistant ability, and water/oxygen-blocking property.

The PI film 220 would be damaged if the PI film 220 is irradiated by a laser having a wavelength within a certain range. Therefore, during manufacturing process of AMOLED substrate 2, it is preferable to avoid the laser from directly irradiating the PI film 220.

The separation layer 230 is used for preventing the PI film 220 from contacting other layers of the AMOLED substrate 2, where such contact would cause damage or corrosion of the PI film 220.

The non-metallic layer 240 is disposed on surface of the separation layer 230. The non-metallic layer 240 does not directly contact the PI film 220, therefore the non-metallic layer 240 would not cause any adverse effect on property of the PI film 220.

The non-metallic layer 240 is composed of amorphous silicon and silicon oxide. Amorphous silicon has good absorption ability for laser having wavelength of 308 nm, and silicon oxide helps to adhere amorphous silicon to the buffer layer 250 that is made of silicon nitride.

A PECVD process is generally used to form the non-metallic layer 240 on the separation layer 230.

The buffer layer 250 is formed from silicon nitride. And, the buffer layer 250 is configured for resulting in a uniform planar surface of the substrate.

The TFT array 260 is formed on the buffer layer 250 using an excimer laser annealing process. Wavelength of an excimer laser used in the excimer laser annealing process is 308 nm.

The present disclosure provides an AMOLED substrate and a method for manufacturing the same. According to the present disclosure, a non-metallic layer is formed on the separation layer in order to absorb a laser passing through the buffer layer during formation of the TFT array, thus preventing any adverse effect caused by the laser on the PI film and increasing manufacturing efficiency of AMOLED substrate.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A method for manufacturing an active matrix organic light-emitting diode (AMOLED) substrate, comprising:
a step S10 of providing a base substrate;
a step S20 of forming a polyimide (PI) film on the base substrate;
a step S30 of forming a separation layer on the PI film;
a step S40 of forming a non-metallic layer on the separation layer;
a step S50 of forming a buffer layer on the non-metallic layer; and
a step S60 of forming a thin film transistor (TFT) array on the buffer layer using an excimer laser annealing process, wherein a wavelength of an excimer laser used in the excimer laser annealing process is 308 nm;
wherein the non-metallic layer formed above the PI film is configured for absorbing a laser passing through the buffer layer during formation of the TFT array.

2. The method for manufacturing an AMOLED substrate according to claim 1, wherein the non-metallic layer includes an amorphous silicon layer and a silicon oxide layer with one stacked on the other.

3. The method for manufacturing an AMOLED substrate according to claim 2, wherein the buffer layer is a silicon nitride layer.

4. The method for manufacturing an AMOLED substrate according to claim 3, wherein the silicon oxide layer is disposed on one surface of the amorphous silicon layer adjoining to the silicon nitride layer.

5. The method for manufacturing an AMOLED substrate according to claim 1, wherein the step S40 includes:
using a plasma enhanced chemical vapor deposition (PECVD) process to form the non-metallic layer on the separation layer.

6. An active matrix organic light-emitting diode (AMOLED) substrate comprising: a base substrate, a polyimide (PI) film, a separation layer, a non-metallic layer, a buffer layer, and a thin film transistor (TFT) array sequentially stacked from bottom to top,
wherein the non-metallic layer disposed above the PI film is configured for absorbing a laser passing through the buffer layer during formation of the TFT array.

7. The AMOLED substrate according to claim 6, wherein the non-metallic layer includes an amorphous silicon layer and a silicon oxide layer with one stacked on the other.

8. The AMOLED substrate according to claim 7, wherein the buffer layer is a silicon nitride layer.

9. The AMOLED substrate according to claim 8, wherein the silicon oxide layer is disposed on one surface of the amorphous silicon layer adjoining to the silicon nitride layer.

10. A method for manufacturing an active matrix organic light-emitting diode (AMOLED) substrate, comprising:
a step S10 of providing a base substrate;
a step S20 of forming a polyimide (PI) film on the base substrate;
a step S30 of forming a separation layer on the PI film;
a step S40 of forming a non-metallic layer on the separation layer;
a step S50 of forming a buffer layer on the non-metallic layer; and
a step S60 of forming a thin film transistor (TFT) array on the buffer layer using an excimer laser annealing process;
wherein the non-metallic layer formed above the PI film is configured for absorbing a laser passing through the buffer layer during formation of the TFT array.

11. The method for manufacturing an AMOLED substrate according to claim 10, wherein the non-metallic layer includes an amorphous silicon layer and a silicon oxide layer with one stacked on the other.

12. The method for manufacturing an AMOLED substrate according to claim 11, wherein the buffer layer is a silicon nitride layer.

13. The method for manufacturing an AMOLED substrate according to claim 12, wherein the silicon oxide layer is disposed on one surface of the amorphous silicon layer adjoining to the silicon nitride layer.

14. The method for manufacturing an AMOLED substrate according to claim 10, wherein the step S40 includes:
using a plasma enhanced chemical vapor deposition (PECVD) process to form the non-metallic layer on the separation layer.
